(19) United States
(12) Patent Application Publication
(10) Pub. No.: US 2007/0138466 A1
(43) Pub. Date: Jun. 21, 2007

(54) Apparatus for testing a semiconductor module

(75) Inventors: Dong-Soo Lee, Seoul (KR); Seon-O Kim, Suwon-si (KR); Yong-Kyun Sun, Cheonan-si (KR); Hyo-Gyu Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/604,822

(22) Filed: Nov. 28, 2006

(30) Foreign Application Priority Data
Dec. 21, 2005 (KR) 2005-126670

(51) Int. Cl. H01L 23/58

(52) U.S. Cl. 257/48

(57) ABSTRACT

An apparatus for testing a semiconductor module may include a test shelf, test modules and a transfer robot. The test shelf may include multilayered test cells in which a plurality of test cells may be arranged in each of a plurality of layers. The test modules may be each provided in the test cells. The transfer robot may insert the semiconductor module into the test module. The transfer robot may separate the semiconductor module from the test module.

### PRIORITY STATEMENT

This application claims benefit of priority under 35 U.S.C. § 119 from Korean Patent Application No. 10-2005-0126670 filed on Dec. 21, 2005, in the Korean Intellectual Property Office, the disclosure of which is incorporated herein by reference in its entirety.

### BACKGROUND

1. Field of the Invention

Example embodiments of the present invention relate to an apparatus for testing a semiconductor module. More particularly, example embodiments of the present invention relate to an apparatus that may test semiconductor modules efficiently.

2. Description of the Related Art

Generally, a semiconductor chip may be formed on a wafer by a semiconductor manufacturing process. The semiconductor chip may be separated from the wafer by an individualizing process. The individually separated semiconductor chips may be packaged to provide a semiconductor device.

The semiconductor device may be combined with a circuit board (e.g., printed circuit board) having a circuit pattern to provide a semiconductor module. The semiconductor module may be tested under various conditions.

Generally, the semiconductor module may have a thin plate-like shape. The semiconductor module may be inserted into a test main board to test the semiconductor module.

A conventional apparatus for testing the semiconductor module may have a test main board in which the semiconductor module may be inserted.

An operator may dispose the semiconductor module on the test main board. The operator may combine the semiconductor module with the test main board manually. The operator may classify the semiconductor module in accordance with the test result.

However, manual testing may consume a significant amount of time. Additionally, when a conventional apparatus for testing the semiconductor module is employed, it may be difficult to increase the number of test main boards used for testing the semiconductor module. Furthermore, in case that the semiconductor module is manually tested, it may be difficult to classify the semiconductor module.

### SUMMARY

Example, non-limiting embodiments of the present invention provide an apparatus for testing a semiconductor module that may shorten a processing time for testing the semiconductor module.

According to an example, non-limiting embodiment, an apparatus for testing a semiconductor module may include a test shelf, test modules and a transfer robot. The test shelf may include multi-layered test cells in which a plurality of test cells may be provided in each of a plurality of layers. The test modules may be respectively provided in the test cells. The transfer robot may function to insert the semiconductor module into the test module. The transfer robot may function to separate the semiconductor module from the test module.

According to an example, non-limiting embodiment, an apparatus for testing a semiconductor module may include a test shelf. The test shelf may include a plurality of test cells. The test cells may be arranged in a matrix having N columns and M rows. Here, N and M may be greater than 1. Test modules may be respectively provided in the test cells. A transfer robot may be provided to insert the semiconductor module into the test module, and to separate the semiconductor module from the test module.

### BRIEF DESCRIPTION OF THE DRAWINGS

Example, non-limiting embodiments of the present invention will be described with reference to the accompanying drawings.

FIG. 1 is a perspective view of an apparatus for testing a semiconductor module in accordance with an example embodiment of the present invention.

FIG. 2 is a cross-sectional view of a loader and an unloader that may be provided at a test shelf shown in FIG. 1.

FIG. 3 is a perspective view of a transfer robot that may be included in the apparatus for testing the semiconductor module in FIG. 1.

FIG. 4 is a cross-sectional view of a guide rail on which a base body illustrated in FIG. 3 may move.

FIG. 5 is a perspective view of a second robot arm in accordance with an example embodiment of the present invention.

FIG. 6 is a cross-sectional view of a first robot hand in accordance with an example embodiment of the present invention.

FIG. 7 is a cross-sectional view of a second robot hand in accordance with an example embodiment of the present invention.

FIG. 8 is a cross-sectional view of a position-recognizing sensor that may be installed between a first robot hand and a test module, and/or between a second robot hand and the test module.

FIG. 9 is a cross-sectional view of an apparatus for testing a semiconductor module in accordance with an example embodiment of the present invention.

### DESCRIPTION OF EXAMPLE, NON-LIMITING EMBODIMENTS

Example, non-limiting embodiments of the present invention are described with reference to the accompanying drawings. The present invention may, however, be embodied in many different forms and should not be construed as limited to the example embodiments set forth herein. Rather, the disclosed embodiments are provided so that the disclosure will be thorough and complete, and will fully convey the scope of the present invention to those skilled in the art. The principles and features of this invention may be employed in varied and numerous embodiments without departing from the scope of the present invention. In the drawings, the size and relative sizes of parts and regions may be exaggerated for clarity. The drawings are not to scale. Like reference numerals designate like elements throughout the drawings.

It will be understood that when an element or layer is referred to as being “on,” “connected to” and/or “coupled to” another element or part, the element or part may be directly on, connected and/or coupled to the other element or part or intervening elements or parts may be present. In contrast, when an element is referred to as being “directly on,” “directly connected to” and/or “directly coupled to” another element or part, no intervening elements or parts are present. As used herein, the term “and/or” may include any and all combinations of one or more of the associated listed items.

Although the terms first, second, etc. may be used herein to describe various elements, components, regions, parts and/or sections, these elements, components, regions, parts and/or sections should not be limited by these terms. The terms may be used to distinguish one element, component, region, part and/or section from another element, component, region, part and/or section. For example, a first element, component, region, part and/or section discussed below could be termed a second element, component, region, part and/or section without departing from the teachings of the present invention.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements and/or features. The device may be otherwise oriented (rotated 90 degrees or at other orientations) and the spatially relative descriptors used herein interpreted accordingly.

The terminology used herein is for the purpose of describing example embodiments only and is not intended to be limiting of the invention. As used herein, the singular terms “a,” “an” and “the” are intended to include the plural forms as well, unless the context clearly indicates otherwise. It will be understood that the terms “includes” and/or “including”, when used in this specification, specify the presence of stated features, integers, elements, components, and/or groups thereof but do not preclude the presence and/or addition of one or more other features, integers, elements, components, and/or groups thereof.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of this specification and the relevant art and will not be interpreted in an idealized and/or overly formal sense unless expressly so defined herein.

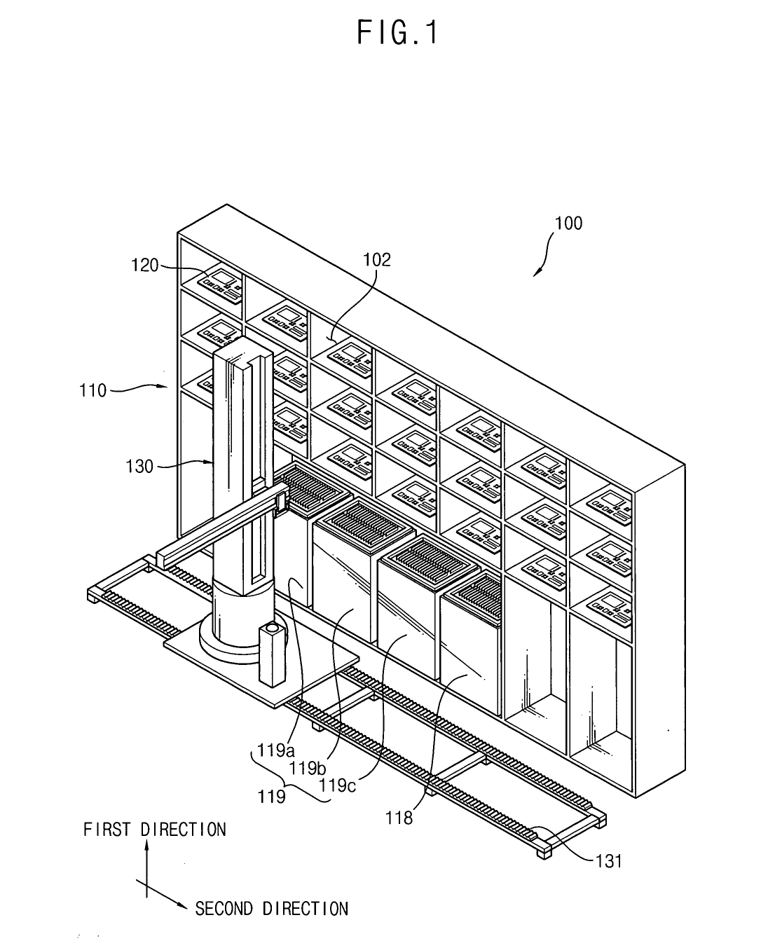

FIG. 1 is a perspective view of an apparatus for testing a semiconductor module in accordance with an example embodiment of the present invention.

Referring to FIG. 1, an apparatus 100 for testing a semiconductor module may include a test shelf 110, test modules 120 and a transfer robot 130.

The test shelf 110 may include test cells 102. The test cells 102 may be arranged in a first direction. The first direction may be a vertical direction (e.g., substantially in parallel with a gravity direction). By way of example only, the number of test cells 102 counted along the first direction may be three.

The test cells 102 may also be arranged in a second direction, which may be substantially perpendicular to the first direction. By way of example only, the number of test cells 102 counted along the second direction may be seven. That is, the test cells 102 of the test shelf 110 may be arranged in a matrix. In FIG. 1, the test cells 102 may be arranged in a 7-by-3 matrix. In alternative embodiments, the dimensions of the test cell matrix may be varied. For example, the test cells 102 of the test shelf 110 may be arranged in a 10-by-3 matrix shape. As another alternative, the test cells 102 of the test shelf 110 may be arranged in a 6-by-6 matrix. The number of test cells 102 (and thus the size of the matrix) may be increased or decreased.

The test module 120 may be provided in the test cell 102 of the test shelf 110. The test module 120 in the test cell 102 may examine a semiconductor module electrically. By way of example only, the test module 120 may include a motherboard having a slit for accommodating the semiconductor module so that the test module 120 and the semiconductor module may be electrically connected together.

As described above, the test cells 102 may be arranged in the first direction and the second direction. Thus, a relatively large number of test modules 120 may be contained in a relatively small area.

A door may be provided at a rear side of the test shelf 110. The door may correspond to the test cell 102. The door may be opened when the test module 120 is repaired and/or changed. Although the test shelf 110 may receive a relatively large number of test modules 120, the test module 120 may be easily repaired and/or changed by having the door.

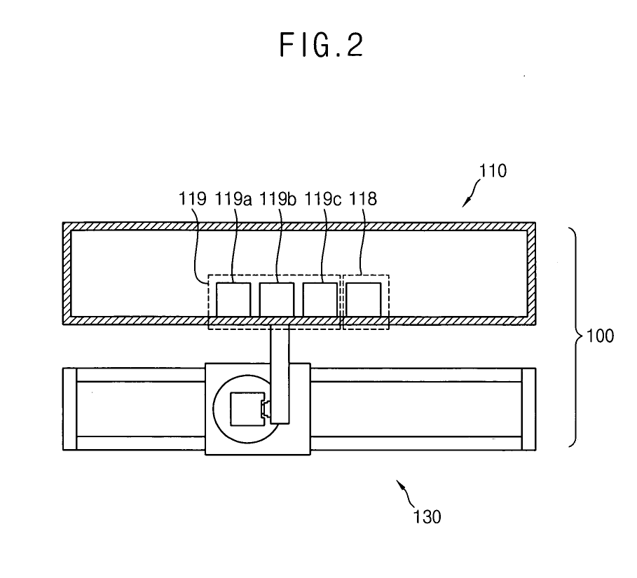

FIG. 2 is a cross-sectional view of a loader and an unloader provided at the test shelf shown in FIG. 1.

The test shelf 110 may include a loader 118 and an unloader 119.

The loader 118 may include a loading tray (not shown) that may receive a semiconductor module that is to be tested by the test module 120.

The unloader 119 may include an unloading tray (not shown) that may receive a semiconductor module that has been tested by the test module 120. By way of example only, the unloader 119 may include a first unloading part 119a, a second unloading part 119b and a third unloading part 119c. The first unloading part 119a may receive a semiconductor module determined as normal (e.g., without defects). The second unloading part 119b may receive a semiconductor module determined as abnormal (e.g., with defects). The third unloading part 119c may receive a semiconductor module that is to be retested.

Referring again to FIG. 1, the test modules 120 may be arranged in the first direction, which may be substantially in parallel with the gravity direction. Also, the semiconductor module may be moved vertically to combine together (and/or separate) the semiconductor module and the test module 120. Thus, it may be difficult to separate the semiconductor modules from the test modules 120 manually. In addition, it may be difficult to combine the semiconductor modules with the test modules 120 manually.

The apparatus 100 for testing the semiconductor module may include a transfer robot 130 to supply the semiconductor modules to the test modules 120 arranged in the first direction.

Although the test cell 102 may have a relatively small dimension, the semiconductor module may be combined with the test module 120 in the test cell 102 by the transfer robot 130. In addition, the semiconductor module may be separated from the test module 120 in the test cell 102 by the transfer robot 130.

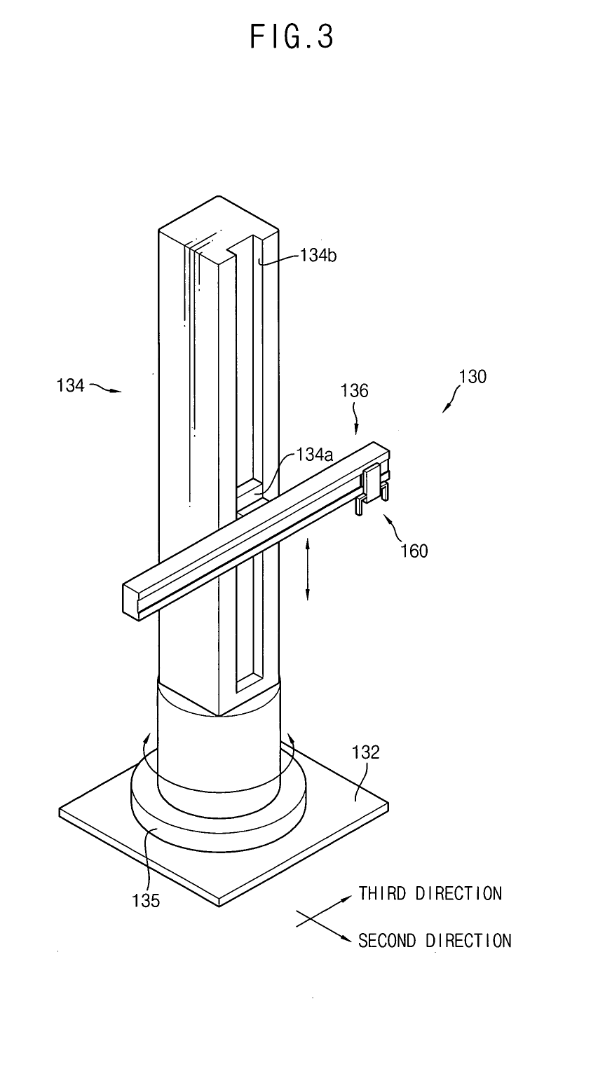

FIG. 3 is a cross-sectional view of a transfer robot that may be included in the apparatus for testing the semiconductor module in FIG. 1.

Referring to FIGS. 1 and 3, a transfer robot 130 may include a base body 132, a first robot arm 134 and a second robot arm 136.

The base body 132 may have a plate shape. The base body 132 may be provided at a front side of the test shelf 110. The base body 132 may move in the second direction. A roller may be provided under the base body 132.

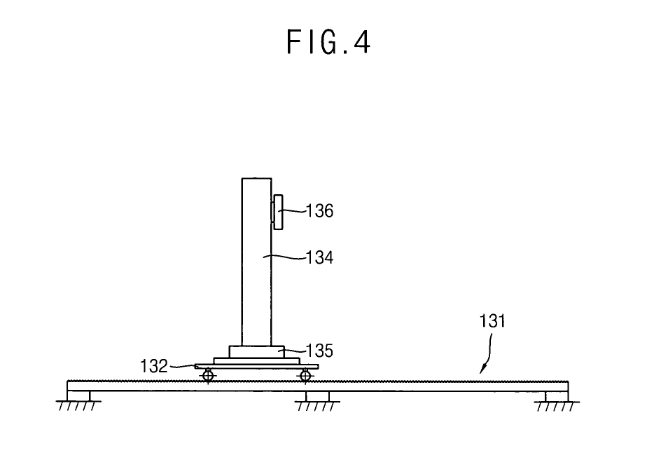

FIG. 4 is a cross-sectional view of a guide rail that may transfer the base body shown in FIG. 3.

Referring to FIGS. 1 and 4, two guide rails 131 may be provided under the base body 132 so that the base body 132 may traverse on the guide rails 131 along the second direction. The guide rails 131 may be substantially in parallel with each other. A pinion gear may be installed on the guide rail 131. A rack gear may be provided to the roller. The pinion gear may be engaged with the rack gear so that the base body 132 may be secured on the guide rails 131. The guide rail 131 may have a plurality of rail pieces so that a length of the guide rail 131 may be extended and/or shortened. The rail pieces may be combined together.

By way of example only, a movement of the base body 132 on the guide rail 131 may be controlled using a hydraulic cylinder and/or a transfer crew.

A first robot arm 134 may be provided on the base body 132. The first robot arm 134 may have a bar shape. The first robot arm 134 may be substantially in parallel with the first direction.

The first robot arm 134 may include a first lifting part 134a. The first lifting part 134a may ascend and/or descend along the first robot arm 134. The first lifting part 134a may be installed in a guide groove 134b that may be provided at a side portion of the first robot arm 134.

A rotor 135 may be provided between the first robot arm 134 and the base body 132. The rotor 135 may rotate the first robot arm 134 in a direction substantially in parallel with the base body 132.

A second robot arm 136 may be installed at the first lifting part 134a of the first robot arm 134. The second robot arm 136 may function to combine the semiconductor module with the test module 120. The second robot arm 136 may function to separate the semiconductor module from the test module 120.

As illustrated in FIG. 3, the second robot arm 136 may realize a linearly reciprocating motion. The second robot arm 136 in FIG. 3 may move in a third direction substantially perpendicular to the second direction. The second robot arm 136 may reciprocate linearly between an “in” position and an “out” position relative to the test cell 102.

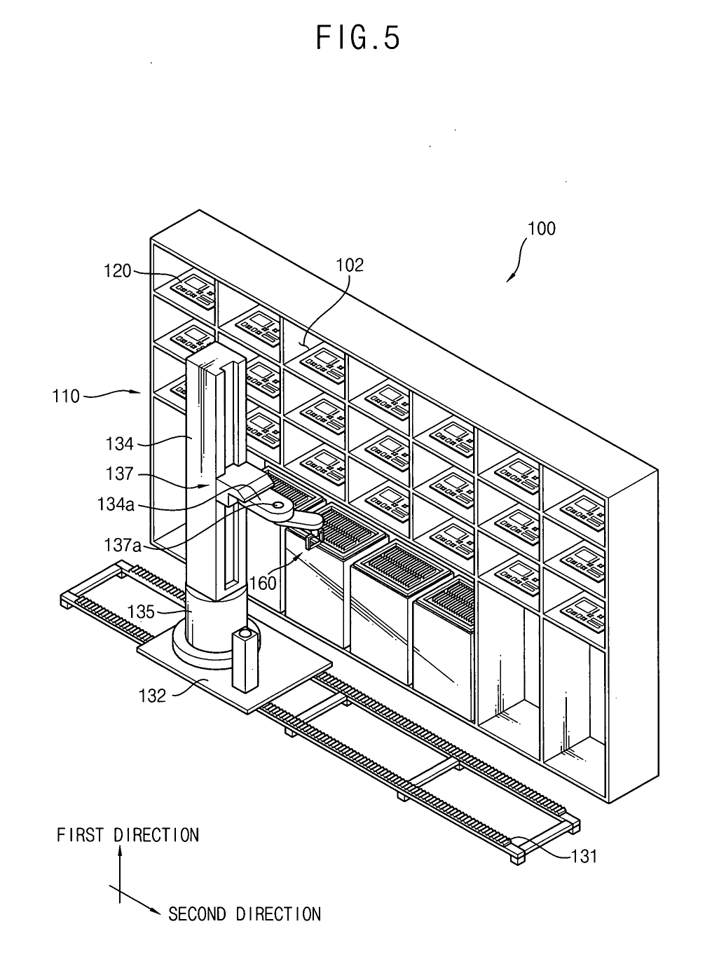

FIG. 5 is a perspective view of a second robot arm in accordance with an example embodiment of the present invention.

Referring to FIG. 5, a second robot arm 137 may be provided at the lifting part 134a of the first robot arm 134. The second robot arm 137 may include a rotor 137a installed at the lifting part 134a of the first robot arm 134. The second robot arm 137 may include at least one joint. The rotor 137a may rotate the second robot arm 137. For example, the rotor 137a may be on an axis of rotation of the second robot arm 137.

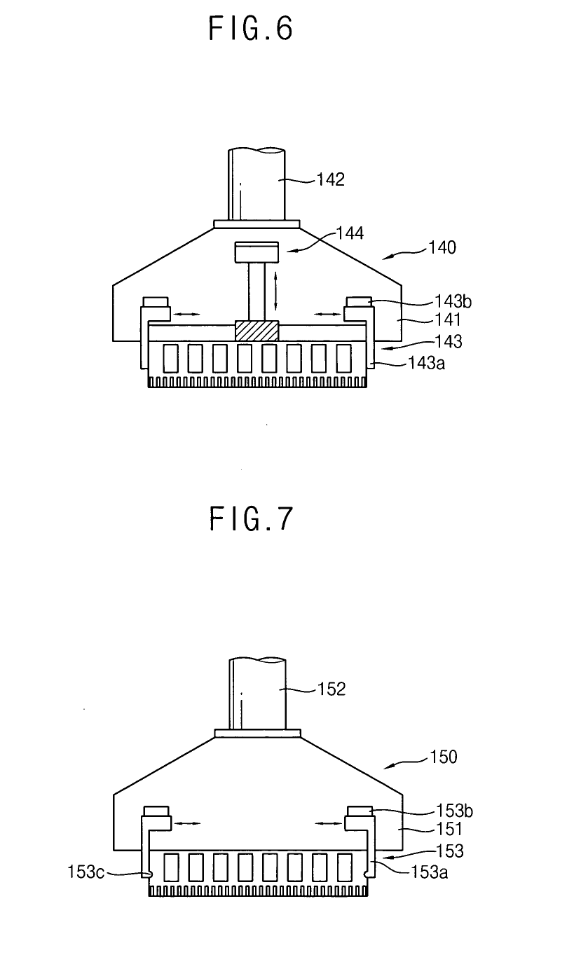

FIG. 6 is a cross-sectional view of a first robot hand 140 in accordance with an example embodiment of the present invention. FIG. 7 is a cross-sectional view of a second robot hand 150 in accordance with an example embodiment of the present invention.

The second robot arm 136 in FIG. 3 may have a robot hand assembly 160. The second robot arm 137 in FIG. 5 may have the robot hand assembly 160.

Referring to FIGS. 6 and 7, the robot hand assembly 160 may include the first robot hand 140 and/or the second robot hand 150.

By way of example only, the first robot hand 140 may insert the semiconductor module into the test module, and the second robot hand 150 may remove the semiconductor module from a test module.

The first robot hand 140 may include a first base plate 141, a first vertical transfer unit 142, first grippers 143 and a shock absorber 144.

The first vertical transfer unit 142 may be connected to an upper end of the first base plate 141. The first vertical transfer unit 142 may transfer the first base plate 141 upwardly and/or downwardly with respect to the second robot arms 136 and 137. The first vertical transfer unit 142 may transfer the first base plate 141 under the second robot arms 136 and 137.

The first gripper 143 may include a pair of first gripper pins 143a and first operation modules 143b. The first operation module 143b may drive the first gripper pin 143a. The first operation modules 143b may be provided on the first base plate 141 such that the first operation modules 143b may be spaced apart from one another. The first gripper pins 143a, which may be respectively installed at the first operation modules 143b, may face each other such that the first gripper pins 143a may grip the semiconductor module. The first operation modules 143b may adjust an interval between the two first gripper pins 143a. If the interval decreases, then the first gripper pins 143a may hold the semiconductor module. If the interval increases, then the semiconductor module may be released from the first gripper pins 143a.

A shock may be applied to the semiconductor module and/or the test module 120 when the semiconductor module gripped by the first gripper 143 of the first robot hand 140 is inserted into the test slit of the test module 120. If the shock is applied to the semiconductor module and/or the test module 120, the semiconductor module and/or the test module 120 may be damaged.

A shock absorber 144 may be implemented to reduce the chance of the semiconductor module and/or the test module 120 being damaged. The shock absorber 144 may be provided on the first base plate 141. A first end of the shock absorber 144 may be fixed to the first base plate 141. A second end of the shock absorber 144 may include a shock-absorbing member (e.g., a rubber member) that may contact with the semiconductor module gripped by the first robot hand 140.

Alternatively, the shock absorber 144 may include a damper fixed to the first base plate 141. A first end of the damper may be fixed to the first base plate 141. A second end of the damper may contact with the semiconductor module gripped by the first robot hand 140.

The damper may be an air damper using a gas (e.g., air). Alternatively, the damper may be a hydraulic damper using a fluid (e.g., an oil). A shock-absorbing member (e.g., a rubber member) may be provided at a portion of the damper that may contact with the semiconductor module.

The first gripper pins 143a of the first gripper 143 included in the first robot hand 140 may grip both side faces of the semiconductor module.

Referring to FIG. 7, the second robot hand 150 may include a second base plate 151, a second vertical transfer unit 152 and second grippers 153.

The second vertical transfer unit 152 may be connected to an upper end of the second base plate 151. The second vertical transfer unit 152 may transfer the second base plate 151 upwardly and/or downwardly with respect to the second robot arms 136 and 137.

The second gripper 153 may include a pair of second gripper pins 153a and second operation modules 153b. The second operation module 153b may drive the second gripper pin 153a. The second operation modules 153b may be arranged on the second base plate 151 such that the second operation modules 153b may be spaced apart from one another. The second gripper pins 153a installed at the second operation modules 153b may face each other such that the second gripper pins 153a may grip the semiconductor module. The second operation modules 153b may adjust an interval between two second gripper pins 153a. If the interval decreases, then the second gripper pins 153a may hold the semiconductor module. If the interval increases, then the semiconductor module may be released from the second gripper pins 153a.

The second gripper pin 153a may include a protruded portion 153c. The protruded portion 153c may be inserted into a recess provided at the side portion of the semiconductor module. If the second vertical transfer unit 152 having the protruded portion 153c inserted into the recess of the semiconductor module ascends, then the semiconductor module may be reliably separated from the test module 120.

Both the first and the second robot hands 140 and 150 shown in FIGS. 6 and 7, respectively, may be installed at each of the second robot arms 136 and 137. In this case, for example, the first robot hand 140 may be substantially in parallel with the second robot hand 150. Alternatively, only one of the first and the second robot hands 140 and 150 may be installed at the second robot arms 136 and 137.

The first robot hand 140 may be installed at a first end of the second robot arm 136 in FIG. 3. The second robot hand 150 may be installed at a second end of the second robot arm 136.

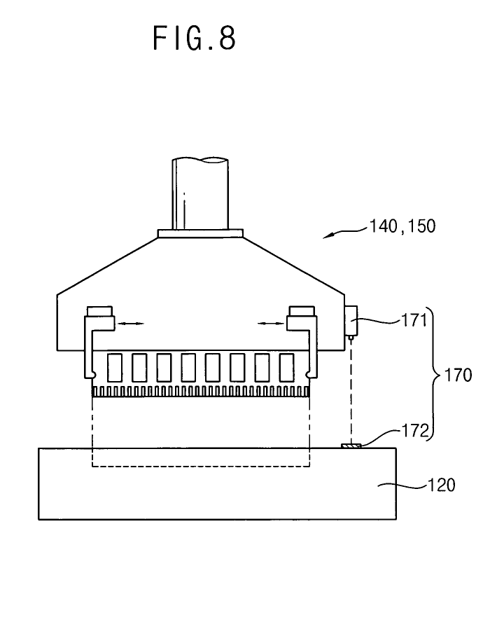

FIG. 8 is a cross-sectional view of a position-recognizing sensor that may be installed between a first robot hand 140 and a test module and/or between a second robot hand 150 and the test module.

Referring to FIGS. 6 to 8, the first robot hand 140 and the test module 120 may together support a position-recognizing sensor 170. In addition, the second robot hand 150 and the test module 120 may together support the position-recognizing sensor 170.

The position-recognizing sensor 170 may adjust positions of the first robot hand 140 and the test module 120 such that the semiconductor module griped by the first robot hand 140 may be inserted into the test module 120. The position-recognizing sensor 170 may adjust positions of the second robot hand 150 and the semiconductor module inserted into the test module 120 such that the second robot hand 150 may grip the semiconductor module.

By way of example only, the position-recognizing sensor 170 may include an align mark recognizing unit 171 and an align mark 172. For example, the align mark recognizing unit 171 may be a CCD (charge coupled device) camera photographing the align mark 172 or a laser beam generator providing an align mask with a laser beam.

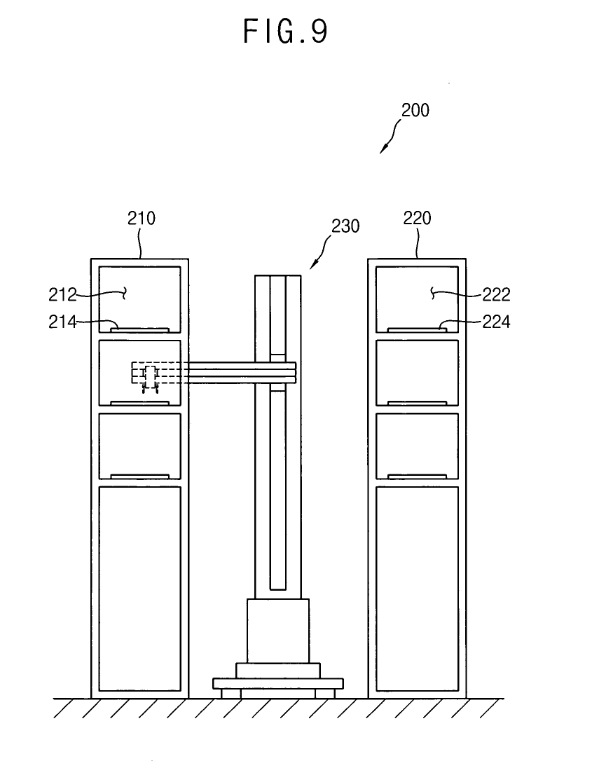

FIG. 9 is a cross-sectional view of an apparatus 200 for testing a semiconductor module in accordance with an example embodiment of the present invention.

The apparatus 200 may be similar to that already illustrated in FIGS. 1 to 8. Thus, any repetitive explanation will be omitted. In addition, the same reference numerals are used in FIG. 9 to designate the same parts as those described in FIGS. 1 to 8.

Referring to FIG. 9, the apparatus 200 for testing a semiconductor module may include a first test shelf 210, a second test shelf 220 and a transfer robot 230. The transfer robot 230 may be provided between the first test shelf 210 and the second test shelf 220.

The first test shelf 210 and the second test shelf 220 may include first test cells 212 and second test cells 222, respectively. The first test cells 212 may be arranged in a matrix shape. The second cells 222 may be arranged in a matrix shape. A first test module 214 and a second test module 224 may be provided in the first test cell 212 and the second test cell 222, respectively.

The transfer robot 230 may combine a first semiconductor module and a second semiconductor module with the first test module 214 and the second test module 224, respectively, to test the first semiconductor module and the second semiconductor module. The first semiconductor module may be different from the second semiconductor module. In an alternative embodiment, the first and the second semiconductor modules may be one in the same, and the first test module 214 and the second test module 224 may function to sequentially test the semiconductor module.

According to example embodiments of the present invention, it may take less time to examine a semiconductor module having a bundle of packaged semiconductors.

The foregoing is illustrative of the present invention and is not to be construed as limiting thereof. Although example embodiments of the invention have been described, those skilled in the art will readily appreciate that many modifications may be suitably implemented without materially departing from the teachings of this invention. Accordingly, all such modifications are intended to be included within the spirit and scope of the invention, as defined in the appended claims.

What is claimed is:

1. An apparatus for testing a semiconductor module, the apparatus comprising:
a test shelf including a plurality of test cells arranged in each of a plurality of layers;
test modules respectively provided in the test cells; and
a transfer robot to insert the semiconductor module into the test module, and to separate the semiconductor module from the test module.

2. The apparatus of claim 1, wherein the test shelf includes a loader having a loading tray and an unloader having an unloading tray, the loading tray to receive a semiconductor module that is to be tested, and the unloading tray to receive a semiconductor module tested by the test module.

3. The apparatus of claim 2, wherein the unloader includes a first part, a second part and a third part, the first part to receive a semiconductor module determined as normal, the second part to receive the semiconductor module determined as abnormal and the third part to receive the semiconductor module to be retested.

4. The apparatus of claim 1, wherein the transfer robot includes:
a base body to move in a horizontal direction along the test cells;
a first robot arm provided on the base body, the first robot arm to move a lifting part in a vertical direction along the test cells; and
a second robot arm installed at the lifting part, the second robot arm to insert the semiconductor module into the test module, and to separate the semiconductor module from the test module.

5. The apparatus of claim 4, wherein the transfer robot includes a guide rail to transfer the base body.

6. The apparatus of claim 4, further comprising a rotor provided between the base body and the first robot arm, the rotor to rotate the first robot arm.

7. The apparatus of claim 4, wherein the second robot arm is rotatable between a first position that is outside of the test cell and a second position that is inside of the test cell.

8. The apparatus of claim 4, wherein the second robot arm is lineally moveable between a first position that is outside of the test cell and a second position that is inside of the test cell.

9. The apparatus of claim 8, wherein the second robot arm includes a first robot hand and a second robot hand, the first robot hand being provided at a first end of the second robot arm, the second robot hand being provided at a second end of the second robot.

10. The apparatus of claim 4, wherein the second robot arm includes a robot hand assembly having a first robot hand for inserting the semiconductor module into the test module and a second robot hand for separating the semiconductor module from the test module.

11. The apparatus of claim 10, wherein the first robot hand includes a first base plate, a first vertical transfer unit, first grippers and a shock absorber, the first vertical transfer unit for transferring the first base plate in a vertical direction, the first grippers installed at the first base plate to grip both side portions of the semiconductor module, the shock absorber installed at the first base plate to absorb a shock applied to the semiconductor module.

12. The apparatus of claim 10, wherein the second robot hand includes a second base plate, a second vertical transfer and second grippers, the second vertical transfer unit for transferring the second base plate in a vertical direction, the second grippers installed at the second base plate and the second grippers to combine with recesses formed at side portions of the semiconductor module.

13. The apparatus of claim 10, further comprising a position-recognizing sensor for recognizing a position of the test module, the position-recognizing sensor provided between the first robot hand and the test module, and the position-recognizing sensor provided between the second robot hand and the test module.

14. The apparatus of claim 13, wherein the position-recognizing sensor is an image pick-up device recognizing an align mark provided on the test module.

15. The apparatus of claim 14, wherein the position-recognizing sensor is a laser optic sensor generating a laser beam provided to the align mark provided on the test module.

16. The apparatus of claim 1, wherein the test shelf includes a first part and a second part, the first and the second parts being provided on opposite sides of the transfer robot.

17. The apparatus of claim 1, wherein a door is provided at a rear side of the test shelf.

18. An apparatus for testing a semiconductor module, the apparatus comprising:
a test shelf including a plurality of test cells arranged in a matrix having N columns and M rows, N and M being greater than 1;
test modules respectively provided in the test cells; and
a transfer robot to insert the semiconductor module into the test module, and to separate the semiconductor module from the test module.
